(19) United States
(12) Patent Application Publication
(10) Pub. No.: US 2026/0333980 A1
(43) Pub. Date: Oct. 22, 2026

(54) ELECTRONIC COMPONENT AND EQUIPMENT

(71) Applicant: CANON KABUSHIKI KAISHA, Tokyo (JP)

(72) Inventor: HIROTO TSUJII, Kanagawa (JP)

(21) Appl. No.: 19/576,364

(22) Filed: Mar. 24, 2026

(30) Foreign Application Priority Data
Apr. 16, 2025 (JP) 2025-067615

(51) Int. Cl. H10H 29/85; H10F 39/00; H10H 29/855

(52) U.S. Cl. CPC H10H 29/8508; H10F 39/804; H10F 39/8063; H10F 39/811; H10H 29/855; H10H 29/857

(57) ABSTRACT

An electronic component is provided. The component includes an element substrate having a first surface including a central region and a peripheral region where a first electrode is arranged, an optical member having a second surface arranged to face the first surface, and a circuit substrate arranged along at least one side of the element substrate, having a third surface arranged to face the second surface, and including a second electrode arranged on the third surface. Third and fourth electrodes electrically connected to each other are arranged on the second surface. The third electrode is arranged at a position overlapping the first electrode and is electrically connected to the first electrode via a bump, and the fourth electrode is arranged at a position overlapping the second electrode and is electrically connected to the second electrode via a bump.

### BACKGROUND

### Field of the Technology

The present disclosure relates to an electronic component and equipment.

### Description of the Related Art

An electronic component that includes a light receiving device or a light emitting device with an optical member arranged on the front surface of the device is demanded to be miniaturized due to space constraints of an image capturing apparatus or the like on which the electronic component is mounted. Japanese Patent Laid-Open No. 2002-299592 describes that, in order to make the packaging structure of an electronic component smaller and thinner, a wiring plate provided with an opening portion above the light receiving portion of an image capturing element is arranged between the image capturing element serving as a light receiving device and a seal member serving as an optical member. This can decrease the space occupied by the electronic component in the apparatus as compared to a case where the image capturing element is arranged in a box-shaped housing.

### SUMMARY

Some embodiments of the present disclosure provide a technique advantageous for further miniaturization of an electronic component.

According to some embodiments, an electronic component comprising: an element substrate having a first surface including a central region where a plurality of elements are arranged, and a peripheral region where a first electrode is arranged; an optical member having a second surface arranged to face the first surface; and a circuit substrate arranged along at least one side of the element substrate, having a third surface arranged to face the second surface, and including a second electrode arranged on the third surface, wherein a third electrode and a fourth electrode electrically connected to each other are arranged on the second surface of the optical member, the third electrode is arranged at a position overlapping the first electrode in an orthogonal projection to a virtual plane including the first surface, and is electrically connected to the first electrode via a first conductive member which is a bump, and the fourth electrode is arranged at a position overlapping the second electrode in an orthogonal projection to the virtual plane, and is electrically connected to the second electrode via a second conductive member which is a bump, is provided.

Features of the present disclosure will become apparent from the following description of embodiments with reference to the attached drawings. The following description of embodiments is described by way of example.

### BRIEF DESCRIPTION OF THE DRAWINGS

FIGS. 1A and 1B are views showing an example of the configuration of an electronic component according to an embodiment;

FIG. 2 is a view showing an example of the configuration of the electronic component according to the embodiment;

FIG. 3 is a view showing an example of the configuration of the electronic component according to the embodiment;

FIG. 4 is a view showing an example of the configuration of the electronic component according to the embodiment;

FIGS. 5A to 5C are views each showing an example of the configuration of the electronic component according to the embodiment;

FIGS. 6A and 6B are views showing an example of the configuration of the electronic component according to the embodiment;

FIGS. 7A and 7B are views showing an example of the configuration of the electronic component according to the embodiment;

FIGS. 8A and 8B are views showing an example of the configuration of the electronic component according to the embodiment;

FIGS. 9A and 9B are views each showing an example of the configuration of the electronic component according to the embodiment; and

FIG. 10 is a view showing an example of the configuration of equipment incorporating the electronic component according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

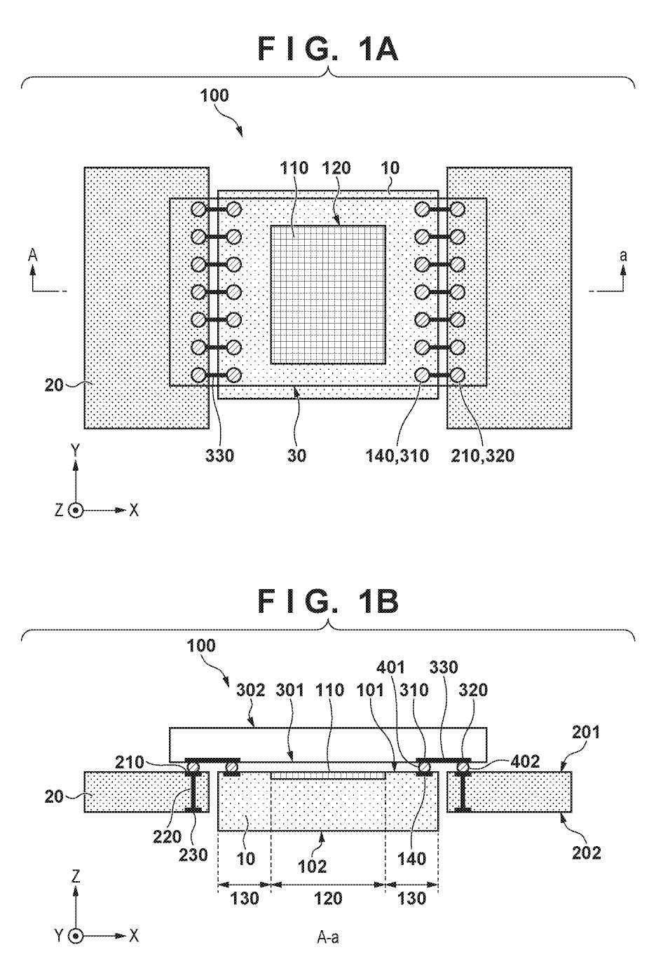

With reference to FIGS. 1A to 9B, an electronic component according to an embodiment of the present disclosure will be described. FIGS. 1A and 1B are schematic views showing an example of the configuration of an electronic component 100 according to this embodiment. FIG. 1A is a schematic plan view of the electronic component 100, and FIG. 1B is a sectional view of the electronic component 100 taken along a line A - a in FIG. 1A. X, Y, and Z directions are indicated in each drawing.

The electronic component 100 can be formed by including an element substrate 10, a circuit substrate 20, and an optical member 30. Here, the X direction and the Y direction are directions along a surface 101 of the element substrate 10. The Z direction is a normal direction to the surface 101 of the element substrate 10. As shown in FIG. 1A, the X direction may be defined as extending in a direction along one side of the surface 101 of the element substrate 10, and the Y direction may be defined as being orthogonal to the X direction. When the surface 101 of the element substrate 10 has a square or rectangular shape, the X direction is a direction parallel to two opposing sides of the surface 101 of the element substrate 10. Similarly, the Y direction is a direction parallel to two opposing sides of the surface 101 of the element substrate 10, which are different from the sides extending in the X direction. Hereinafter, a size in the Z direction may be expressed as a thickness or a depth. Each of the typical element substrate 10 and electronic component 100 has the Z-direction size smaller than the X- and Y-direction sizes. The element substrate 10 and the electronic component 100 can have an almost flat plate shape.

The material used for the element substrate 10 is not particularly limited. Typically, the element substrate 10 can be a semiconductor substrate, for example, a silicon substrate. In this embodiment, the element substrate 10 will be described as functioning as an optical device such as an image capturing device, a display device, or a light emitting device. The element substrate 10 has the surface 101 including a central region 120 where a plurality of elements 110 are arranged in an array, and a peripheral region 130. When the element substrate 10 is an image capturing device, the element 110 is a light receiving element that converts incident light (electromagnetic wave) into an electric signal. A pn photodiode, a pin type photodiode, an avalanche photodiode (APD), or the like can be used as the light receiving element. When the element substrate 10 is a light emitting device, the element 110 is a light emitting element that emits light (electromagnetic wave) corresponding to an input signal. A light emitting diode (LED), an organic LED (OLED) using an organic electroluminescence (OEL), a vertical cavity surface emitting laser (VCSEL), or the like can be used as the light emitting element. Peripheral circuits such as a driving circuit, a control circuit, a signal processing circuit, and an output processing circuit may be arranged in the peripheral region 130. Electrodes 140 serving as terminals for signal input/output and power supply to the element substrate 10 are also arranged in the peripheral region 130. In the configuration shown in FIGS. 1A and 1B, the element substrate 10 is shown to have a single layer structure. However, the element substrate 10 is not limited to this, and may be formed by stacking two or more substrates. In that case, the element substrate 10 may be formed by stacking a substrate arranged with the peripheral circuit below the central region 120 of a substrate arranged with the plurality of elements 110.

The circuit substrate 20 may be a substrate mounted with electronic circuits that implement various functions. The specific functions can be functions of supplying a control signal or power to the element 110 provided in the element substrate 10, processing a signal output from the element substrate 10, storing a signal, transmitting a signal to a computer or a network outside the electronic component 100, and the like. It can be said that the electric circuit arranged in the circuit substrate 20 is a circuit for operating the plurality of elements 110 arranged in the element substrate 10.

The optical member 30 is arranged, for example, to protect the element 110. When the element 110 is a light receiving element, the optical member 30 transmits light having a wavelength received by the element 110. When the element 110 is a light emitting element, the optical member 30 transmits light having a wavelength emitted by the element 110. For example, a transparent member made of glass, silica glass, quartz, or the like can be used for the optical member 30. In accordance with the specifications of the electronic component 100, anti-reflection coating may be applied to the optical member 30, a member that easily transmits infrared light may be used for the optical member 30, or infrared transmissive coating may be applied to the optical member 30. The optical member 30 has a surface 301 arranged to face the surface 101 of the element substrate 10. Electrodes 310 and 320 electrically connected to each other by wiring patterns 330 are arranged on the surface 301 of the optical member 30.

The circuit substrate 20 has a surface 201 arranged to face the surface 301 of the optical member 30, and a surface 202 on the opposite side of the surface 201. Electrodes 210 are arranged on the surface 201 of the circuit substrate 20. Electrodes 230 may be arranged on the surface 202 of the circuit substrate 20. For example, the electrode 210 and the electrode 230 may be electrically connected via a wiring pattern 220 in the circuit substrate 20. For example, the electrodes 210 and the electrodes 230 can be connected to electric circuits mounted in the circuit substrate 20.

Here, the electrode 310 arranged on the surface 301 of the optical member 30 is arranged at a position overlapping the electrode 140 arranged on the surface 101 of the element substrate 10 in an orthogonal projection to a virtual plane including the surface 101 of the element substrate 10, and electrically connected to the electrode 140 via a conductive member 401. The electrode 320 arranged on the surface 301 of the optical member 30 is arranged at a position overlapping the electrode 210 arranged on the surface 201 of the circuit substrate 20 in an orthogonal projection to a virtual plane including the surface 101 of the element substrate 10, and electrically connected to the electrode 210 via a conductive member 402. With this, the electrode 140 arranged on the surface 101 of the element substrate 10 and the electrode 210 arranged on the surface 201 of the circuit substrate 20 are electrically connected. Accordingly, the peripheral circuit arranged in the element substrate 10 is connected to the electric circuit arranged in the circuit substrate 20, thereby making it possible to, for example, control operations of the plurality of elements 110. Input/output of signals or the like between the circuit substrate 20 and the outside of the electronic component 100 may be performed via, for example, electrodes (terminals) arranged on the surface 201 of the circuit substrate 20, which are not shown in FIGS. 1A and 1B. Alternatively, in a case where the electrode 230 is arranged on the surface 202 of the circuit substrate 20 and connected to the electrode 210 as described above, input/output of signals or the like between the circuit substrate 20 and the outside of the electronic component 100 may be performed via the electrodes 230. In this case, input/output of signals between the outside of the electronic component 100 and the element substrate 10 via the circuit substrate 20 can be performed on both the surfaces 201 and 202 of the circuit substrate 20. Hence, by appropriately designing the routing of the wiring pattern 220, miniaturization of the circuit substrate 20 can be achieved.

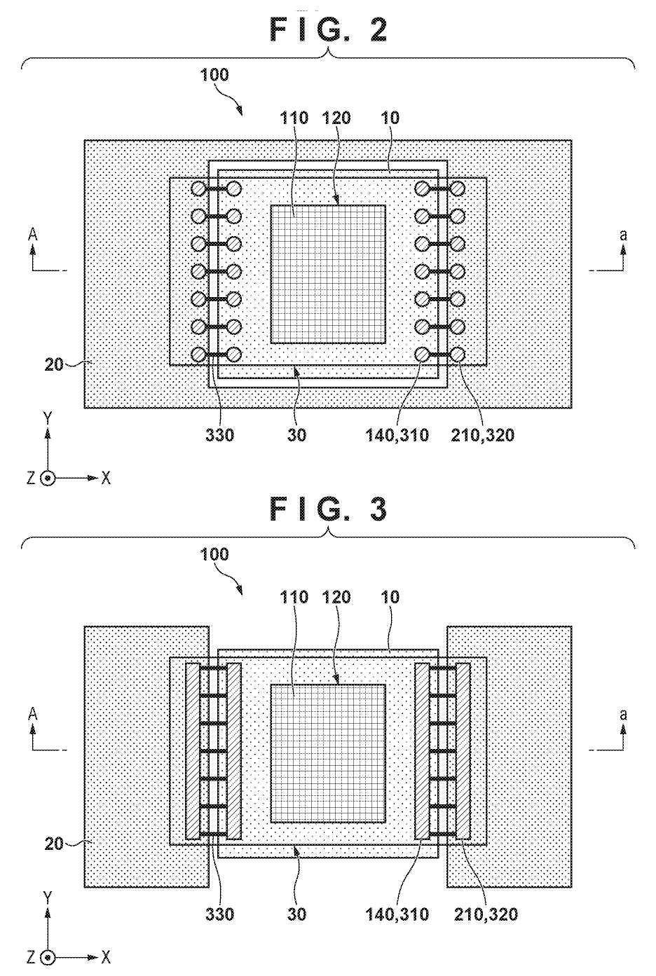

As shown in FIGS. 1A and 1B, the circuit substrate 20 is arranged outside the element substrate 10. In this case, the circuit substrate 20 is not limited to being arranged while being separated into two parts along two sides of the element substrate 10 as shown in FIGS. 1A and 1B. One circuit substrate 20 may be arranged along one side of the element substrate 10, or three or four circuit substrates 20 may be arranged along three or four sides of the element substrate 10. Alternatively, for example, as shown in FIG. 2, an opening portion larger than the element substrate 10 in an orthogonal projection to a virtual plane including the surface 101 of the element substrate 10 may be provided in the circuit substrate 20. In that case, the element substrate 10 may be arranged to be surrounded by the inner edge of the opening portion provided in the circuit substrate 20. The shape and arrangement of the circuit substrate 20 may be decided, as appropriate, in accordance with the functions and configurations required for the circuit substrate 20, the functions and configurations of the elements and circuits mounted on the element substrate 10, and the like. For example, in the configuration shown in FIG. 1A, a plurality of electrodes 140 and a plurality of electrodes 210 are arranged on the surface 101 of the element substrate 10 and the surface 201 of the circuit substrate 20, respectively, along the Y direction. However, the configuration is not limited to this. As shown in FIG. 3, one electrode 140 and one electrode 210 may be arranged on the Y-direction sides, respectively. Appropriate configurations of the electrodes 140, 210, 310, and 320 can be used in accordance with signal input/output and power supply to the element substrate 10.

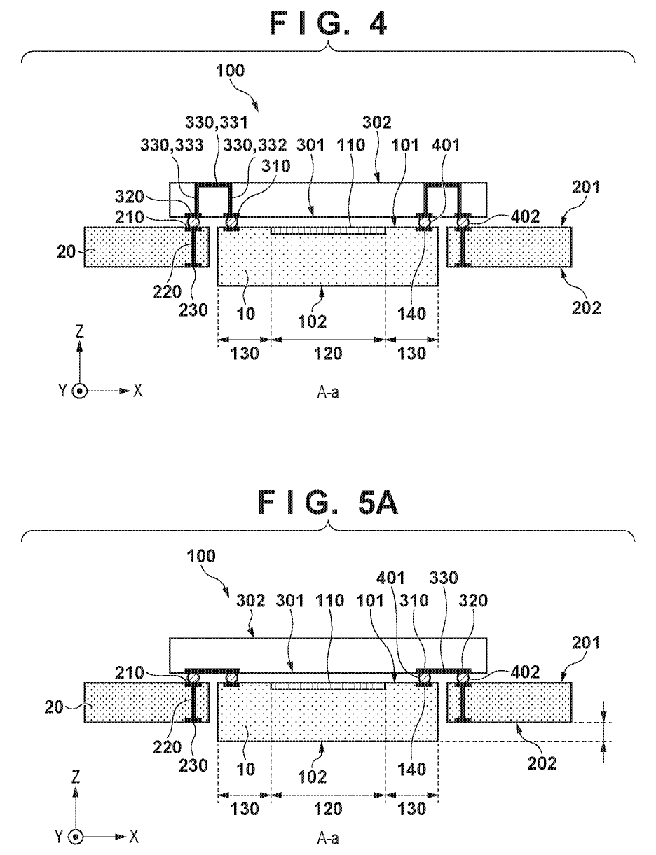

In the configuration shown in FIG. 1B, the electrodes 310 and 320 arranged on the surface 301 of the optical member 30 are electrically connected to each other by the wiring pattern 330 arranged on the surface 301. It can also be said that the electrode 310 and the electrode 320 are formed integrally on the surface 301. However, the connection between the electrode 310 and the electrode 320 is not limited to this. For example, as shown in FIG. 4, the wiring pattern 330 electrically connecting the electrode 310 and the electrode 320 may include a portion 331 arranged on a surface 302 of the optical member 30 on the opposite side of the surface 301, a portion 332 connecting the electrode 310 and the portion 331, and a portion 333 connecting the electrode 320 and the portion 331. In this manner, the electrode 310 and the electrode 320 may be electrically connected by the wiring pattern 330 passing within the optical member 30.

For the conductive members 401 and 402, for example, gold bumps or the like can be used. Here, as shown in FIG. 1B, a plurality of electrodes 140 are arranged on the surface 101 of the element substrate 10. Similarly, a plurality of electrodes 310 are arranged on the surface 301 of the optical member 30. Accordingly, a plurality of conductive members 401, each connecting one of the plurality of electrodes 140 to the corresponding electrode 310 among the plurality of electrodes 310, are arranged in the electronic component 100. The conductive members 401 are required to accurately keep a constant spatial distance between the surface 101 of the element substrate 10 and the surface 301 of the optical member 30. That is, it is required that the thicknesses of the plurality of conductive members 401 arranged in the electronic component 100 are uniform in the direction crossing the surface 101. One reason for this is that the accuracy and efficiency of light reception, display, or light emission of the elements 110 can be improved. If the distance between the surface 101 of the element substrate 10 and the surface 301 of the optical member 30 changes in a plane, for example, the light reception amount or the light emission amount observed via the optical member 30 can change among the plurality of elements 110. The gold bump is more suitable for the space control as compared to a solder bonding and the like.

Here, the distance between the surface 101 of the element substrate 10 and the surface 301 of the optical member 30 can be, for example, about 10 μm to 200 μm, and an appropriate value can be selected in accordance with the size of the element 110 or the like. The thickness of the optical member 30 can be, for example, about 0.2 mm to 1.0 mm. If the optical member 30 is excessively thin, this can influence the strength and deformation. If the optical member 30 is excessively thick, this can hinder miniaturization. A proper thickness of the optical member 30 is selected in consideration of the thickness of the circuit substrate 20, the distance between the surface 101 of the element substrate 10 and the surface 301 of the optical member 30, and the like.

Regarding the connection between the element substrate 10 and the optical member 30 and the connection between the circuit substrate 20 and the optical member 30, only the conductive members 401 and 402 may implement both the electric connection and the mechanical connection, as shown in FIG. 1B. However, the present disclosure is not limited to this. The mechanical strength may be compensated by arranging a resin such as an underfill agent around the conductive members 401 and 402. That is, a resin may be arranged in a gap between the element substrate 10 and the optical member 30, and a resin may be arranged in a gap between the optical member 30 and the circuit substrate 20.

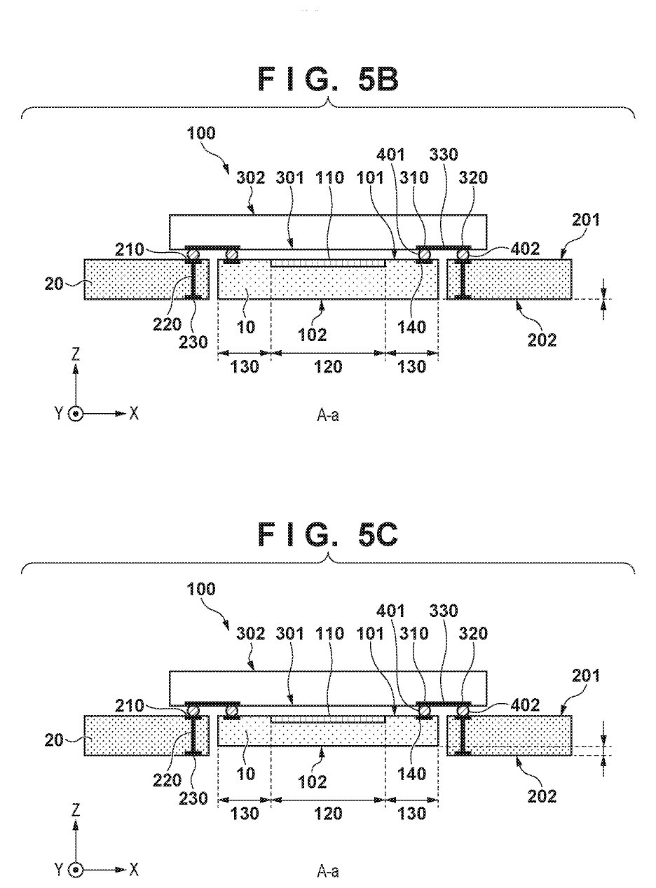

Each of FIGS. 5A to 5C is a schematic sectional view of the electronic component 100, showing an example of the positions and thicknesses of the element substrate 10 and the circuit substrate 20 in the Z direction. As shown in FIGS. 1B and 5A to 5C, the surface 201 of the circuit substrate 20 may be arranged on a virtual plane including the surface 101 of the element substrate 10. It can also be said that the surface 101 of the element substrate 10 and the surface 201 of the circuit substrate 20 are arranged at the same height in the Z direction. To miniaturize the electronic component 100 in the Z direction, the distance between the optical member 30 and the element substrate 10 and the distance between the optical member 30 and the circuit substrate 20 may be set to the minimum distance in the manufacturing process. To achieve this, the surface 101 of the element substrate 10 and the surface 201 of the circuit substrate 20 may be arranged at the same height in the Z direction. Here, the same height may include, for example, a manufacturing error. The manufacturing error can be, for example, about 5 %. This can also be applied to other constituent elements.

In this manner, the surface 101 of the element substrate 10 and the surface 201 of the circuit substrate 20 are arranged at almost the same height in the Z direction. In this case, for example, as shown in FIG. 5A, the thickness of the element substrate 10 in a direction crossing the surface 101 may be larger than the thickness of the circuit substrate 20 in the Z direction. Alternatively, for example, as shown in FIG. 5B, the thickness of the element substrate 10 in the Z direction may be equal to the thickness of the circuit substrate 20 in the Z direction. In a case where the thickness of the element substrate 10 in the Z direction crossing the surface 101 is equal to or larger than the thickness of the circuit substrate 20 in the Z direction, it can be easy to provide a configuration where a cooling member is arranged below the element substrate 10 in FIGS. 5A or 5B to easily cool the element substrate 10. On the other hand, as shown in FIG. 5C, the thickness of the element substrate 10 in the Z direction may be smaller than the thickness of the circuit substrate 20 in the Z direction. The configurations as shown in FIGS. 5B and 5C in which the thickness of the element substrate 10 in the Z direction crossing the surface 101 is equal to or smaller than the thickness of the circuit substrate 20 in the Z direction can be advantageous for miniaturizing (thinning) the electronic component 100 in the Z direction. In a case where the thickness of the element substrate 10 in the Z direction is smaller than the thickness of the circuit substrate 20 in the Z direction as shown in FIG. 5C, this can suppress scratches and foreign matter adhesion on a surface 102 of the element substrate 10 on the opposite side of the surface 101.

With reference to FIGS. 5A to 5C, the thickness relationship between the element substrate 10 and the circuit substrate 20 in the case where the surface 101 of the element substrate 10 and the surface 201 of the circuit substrate 20 are arranged at almost the same height in the Z direction has been described. However, the surface 101 of the element substrate 10 and the surface 201 of the circuit substrate 20 may be arranged at different positions in the Z direction. In that case, the above-described thickness relationship between the element substrate 10 and the circuit substrate 20 cannot be defined. Then, for example, the configuration shown in FIG. 5A can also be said to be a configuration where the surface 102 of the element substrate 10 on the opposite side of the surface 101 protrudes from the surface 202 of the circuit substrate 20. That is, this is the configuration where the surface 102 of the element substrate 10 is arranged at a position farther from the surface 301 of the optical member 30 than the surface 202 of the circuit substrate 20. Similarly, the configuration shown in FIG. 5B is a case where the surface 102 of the element substrate 10 is arranged at the same height with respect to the surface 301 of the optical member 30 (arranged at the same height in the Z direction) as the surface 202 of the circuit substrate 20. Similarly, the configuration shown in FIG. 5C is a case where the surface 102 of the element substrate 10 is arranged closer to the surface 301 of the optical member 30 than the surface 202 of the circuit substrate 20.

In the electronic component 100, the element substrate 10 and the circuit substrate 20 are arranged side by side so as to face the optical member 30. This enables the electronic component 100 to be made smaller in the Z direction than in a configuration where the element substrate 10 is mounted on the circuit substrate 20 and the optical member 30 is mounted on the element substrate 10, and a configuration where the circuit substrate 20 is mounted on the element substrate 10 and the optical member 30 is mounted on the circuit substrate 20. In this embodiment, the electrode 140 arranged on the surface 101 of the element substrate 10 and the electrode 210 arranged on the surface 201 of the circuit substrate 20 are connected via the electrodes 310 and 320 arranged on the surface 301 of the optical member 30. Connecting the electrode 140 and the electrode 210 via the optical member 30 can make the distance therebetween in one of the X direction and the Y direction, which is the extending direction of the wire, shorter than in a case of connecting the electrode 140 and the electrode 210 by wire bonding. That is, miniaturization of the electronic component 100 in the X direction and the Y direction (the X direction in the configuration shown in FIGS. 1A and 1B) can also be achieved. Furthermore, if the element substrate 10 is mounted on the circuit substrate 20, the thermal curing of a bonding material for bonding the element substrate 10 to the circuit substrate 20 may cause warpage of the element substrate 10, and the spatial distance between the element substrate 10 and the optical member 30 can vary in the plane of the surface 101. On the other hand, in the configuration according to this embodiment, the bonding between the element substrate 10 and the optical member 30 is the local bonding by the conductive member 401 (and the underfill agent if used). This can reduce the warpage of the element substrate 10, thereby suppressing the variation in distance between the surface 101 of the element substrate 10 and the optical member 30. Hence, by using the configuration according to this embodiment, it is possible to provide the electronic component 100 that achieves not only miniaturization of the electronic component 100 but also highly accurate position (distance) alignment with reduced variation between the elements 110 arranged in the element substrate 10 and the optical member 30.

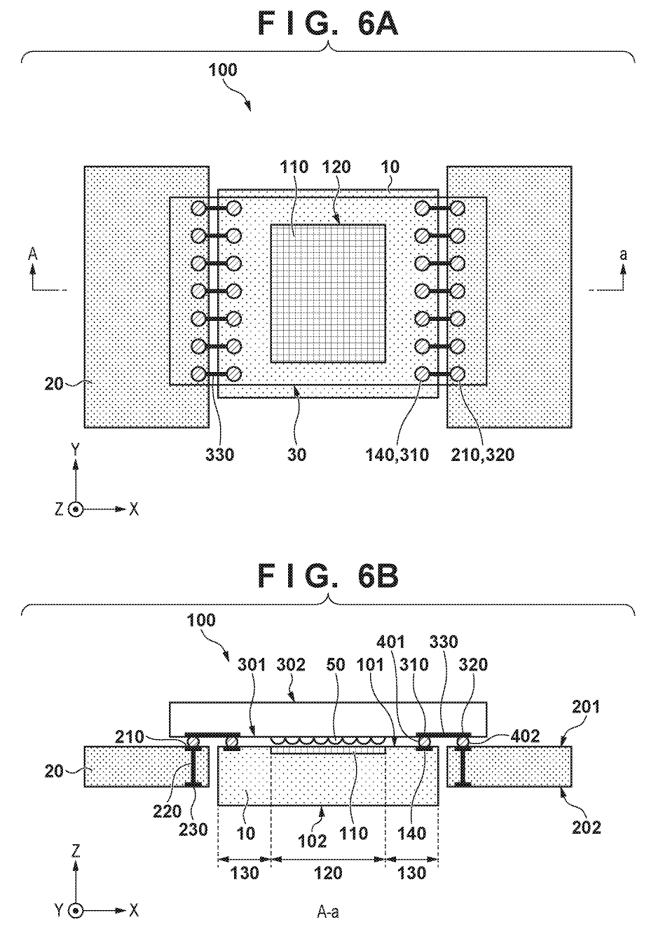

FIGS. 6A and 6B are views showing a modification of the electronic component 100 shown in FIGS. 1A and 1B. In the configuration shown in FIGS. 6A and 6B, a plurality of microlenses 50 are arranged on the surface 301 of the optical member 30 so as to correspond to the plurality of elements 110, respectively. The microlens 50 is formed to match the size of the element 110 arranged in the element substrate 10. For example, the plurality of microlenses 50 may be formed to have the same pitch and array as the plurality of elements 110, and at least as many microlenses 50 as the elements 110 may be formed. However, the plurality of microlenses 50 are not limited to this. For example, the plurality of microlenses 50 may be arranged so as to correspond to some of the plurality of elements 110. Alternatively, for example, the plurality of microlenses 50 may be arranged such that one microlens 50 corresponds to a predetermined number of the elements 110 (for example, four elements 110 including two in the X direction and two in the Y direction).

The microlens 50 may be formed integrally with the optical member 30. For example, the optical member 30 including the microlens 50 on the surface 301 may be formed by appropriately processing a material for the optical member 30 using silica glass. Alternatively, for example, the microlens 50 may be formed by forming an appropriate material layer made of a resin or the like on the surface 301 of the optical member 30 and processing the material layer. Furthermore, for example, the processed microlens 50 may be adhered onto the surface 301 of the optical member 30. Various appropriate methods can be used to arrange the microlens 50 on the surface 301 of the optical member 30.

Considering the light condensing rate and the like, the height of each microlens 50 may be 1/2 or less of the diameter of each microlens 50. When mounting the optical member 30 on the element substrate 10, it is mounted such that the position of each of the plurality of elements 110 matches the position of the corresponding microlens 50 in the X direction and the Y direction. For alignment between the element 110 and the microlens 50, for example, alignment marks are provided at appropriate positions on the element substrate 10 and the optical member 30, respectively. By using a camera installed in a mounting apparatus, that mounts the optical member 30 on the element substrate 10, to perform mounting while recognizing the respective alignment marks, it is possible to accurately align the optical member 30 and the element substrate 10.

The configuration shown in FIGS. 6A and 6B can suppress the variation in distance between the elements 110 arranged in the surface 101 of the element substrate 10 and the optical member 30, similar to the configuration described above, and the microlens 50 can improve condensing of light. That is, it is possible to provide the electronic component 100 that achieves miniaturization of the electronic component 100, highly accurate distance alignment between the elements 110 arranged in the element substrate 10 and the optical member 30, and highly accurate alignment between the elements 110 and the microlenses 50.

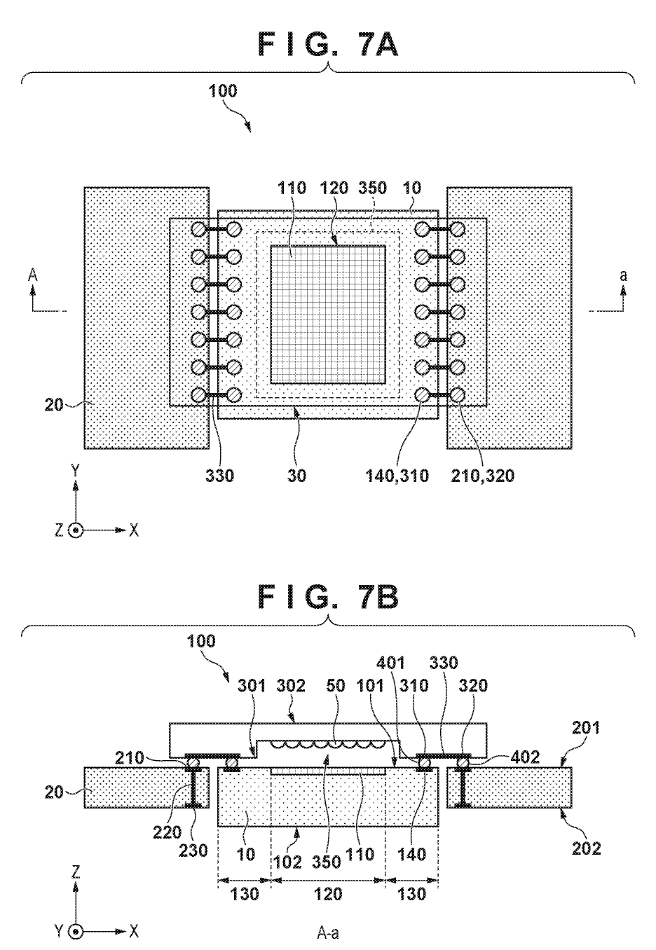

FIGS. 7A and 7B are views showing a modification of the electronic component 100 shown in FIGS. 1A and 1B. In the configuration shown in FIGS. 7A and 7B, the optical member 30 includes a concave portion 350 on the surface 301. In an orthogonal projection to a virtual plane including the surface 101 of the element substrate 10, the outer edge of the concave portion 350 is arranged between the central region 120 and the outer edge of the element substrate 10. Similar to the configuration shown in FIGS. 6A and 6B, the plurality of microlenses 50 are arranged in the concave portion 350 of the surface 301 of the optical member 30 so as to correspond to the plurality of elements 110, respectively. In the configuration shown in FIGS. 7A and 7B, the distance between the surface 101 of the element substrate 10 and the microlens arranged on the surface 301 of the optical member 30 can be, for example, about 10 μm to 200 μm, and an appropriate value can be selected in accordance with the size of the element 110 and the like. This can also be applied to the configuration shown in FIGS. 6A and 6B.

The configuration of the optical member 30 shown in FIGS. 7A and 7B can be advantageous for, for example, achieving both the strength of a portion that bonds with the element substrate 10 and the circuit substrate 20, and the optical characteristics of a portion that faces the plurality of elements 110 and transmits light. For example, if the surface 101 of the element substrate 10 and the surface 301 of the optical member 30 are arranged close to miniaturize the electronic component 100 in the Z direction, the microlens 50 may not be able to be arranged on the surface 301 of the optical member 30. In that case, by providing the concave portion 350, the microlens 50 can be arranged. With this configuration as well, it is possible to provide the electronic component 100 that achieves miniaturization of the electronic component 100, highly accurate distance alignment between the elements 110 arranged in the element substrate 10 and the optical member 30, and highly accurate alignment between the elements 110 and the microlenses 50.

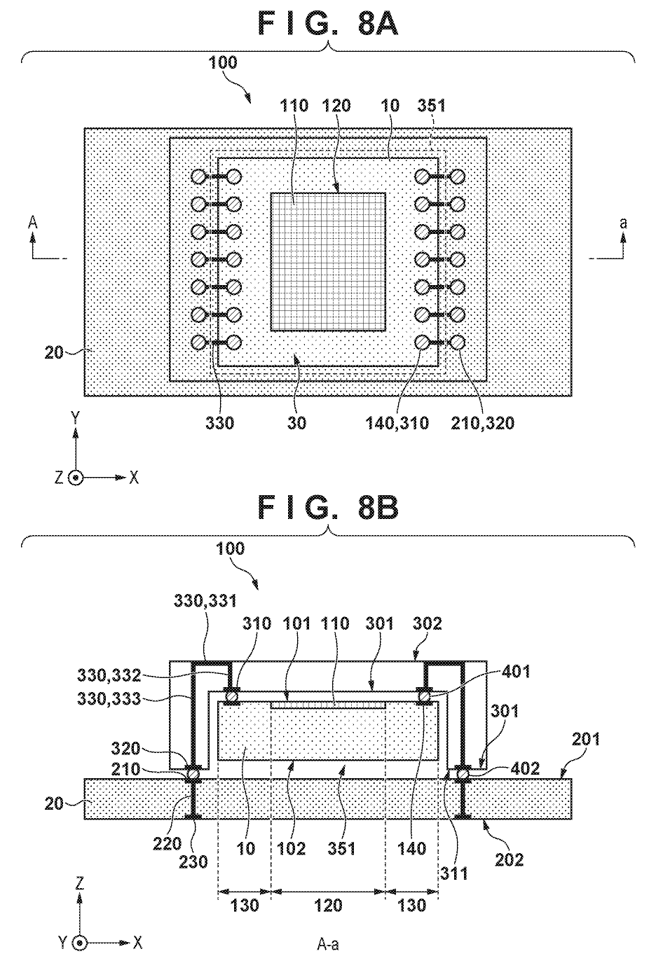

FIGS. 8A and 8B are views showing a modification of the electronic component 100 shown in FIGS. 1A and 1B. In the configuration shown in FIGS. 8A and 8B, the optical member 30 includes a concave portion 351 on the surface 301. The concave portion 351 is larger than the concave portion 350 shown in FIGS. 7A and 7B described above, and the outer edge of the concave portion 351 is arranged outside the outer edge of the element substrate 10 in an orthogonal projection to a virtual plane including the surface 101 of the element substrate 10. That is, the optical member 30 includes the concave portion 351 larger than the outer shape of the element substrate 10 in the X direction and the Y direction, and the electrode 310 is arranged in the concave portion 351 of the surface 301. In this case, at least a part of the element substrate 10 is arranged in the concave portion 351.

As shown in FIG. 8B, the wiring pattern 330 connecting the electrode 310 and the electrode 320 may include the portion 331 arranged on the surface 302 of the optical member 30 on the opposite side of the surface 301, the portion 332 connecting the electrode 310 and the portion 331, and the portion 333 connecting the electrode 320 and the portion 331. Alternatively, for example, the wiring pattern 330 may be arranged along the surface 301 of the optical member 30.

In the configuration shown in FIGS. 8A and 8B, the element substrate 10 is arranged above the circuit substrate 20. Therefore, as compared to each configuration described above, miniaturization in the Z direction can be limited. However, by connecting the electrode 140 arranged on the element substrate 10 and the electrode 210 arranged on the circuit substrate 20 via the optical member 30, miniaturization in the X direction and the Y direction can be achieved. In addition, as described above, since the element substrate 10 is bonded to the optical member 30 by the conductive member 401, warpage of the element substrate 10, which occurs when bonding the element substrate 10 to the circuit substrate 20, can be suppressed. That is, with the configuration shown in FIGS. 8A and 8B as well, it is possible to provide the electronic component 100 that achieves both miniaturization of the electronic component 100 and highly accurate alignment between the elements 110 arranged in the element substrate 10 and the optical member 30.

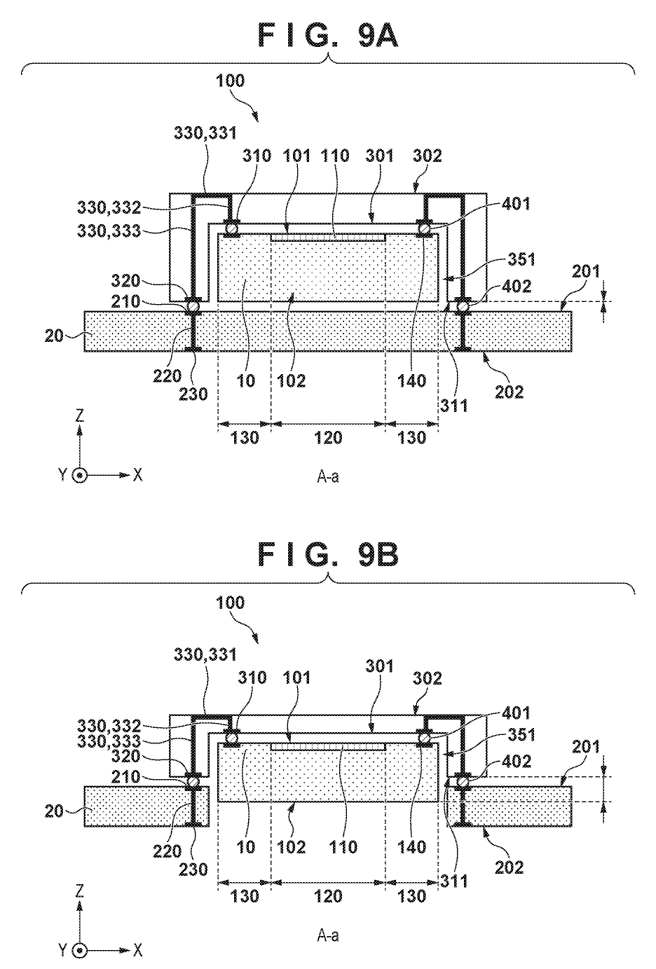

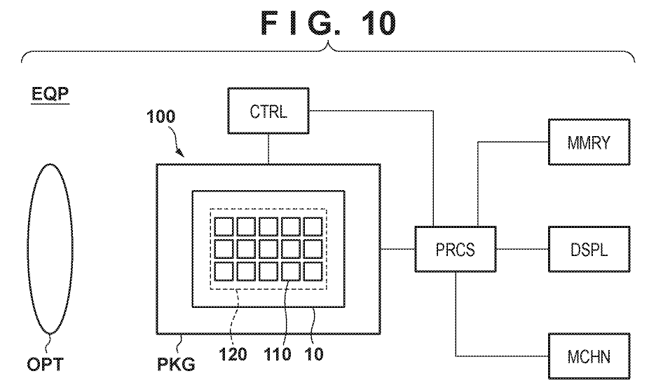

As shown in FIG. 8B, the surface 102 of the element substrate 10 on the opposite side of the surface 101 may be arranged closer to the surface 302 of the optical member 30 on the opposite side of the surface 301 than an outer edge portion 311 surrounding the concave portion 351 of the surface 301 of the optical member 30. Alternatively, for example, as shown in FIG. 9A, the surface 102 of the element substrate 10 on the opposite side of the surface 101 may be arranged at the same height as the outer edge portion 311 surrounding the concave portion 351 of the surface 301 of the optical member 30 with respect to the surface 302 of the optical member 30 on the opposite side of the surface 301. The concave portion 351 provided on the surface 301 of the optical member 30 accommodates the element substrate 10. For example, in a step of bonding the optical member 30 and the circuit substrate 20, this can suppress a failure such as damage of the element substrate 10. However, the present disclosure is not limited to this. As shown in FIG. 9B, the surface 102 of the element substrate 10 on the opposite side of the surface 101 may be arranged at a position farther from the surface 302 of the optical member 30 on the opposite side of the surface 301 than the outer edge portion 311 surrounding the concave portion 351 of the surface 301 of the optical member 30. In this case, as shown in FIG. 9B, an opening portion larger than the outer edge of the element substrate 10 in the X direction and the Y direction may be provided in the circuit substrate 20. For example, in the configuration shown in FIG. 9B, it is possible to bond the optical member 30 and the circuit substrate 20, and then bond the optical member 30 and the element substrate 10. With the configuration shown in FIG. 9B, the degree of freedom in the manufacturing step concerning temperature management during each bonding process or the like can be higher than in the configurations shown in FIGS. 8B and 9A.

Each embodiment described above is not limited to that described with reference to the corresponding drawings, and various modifications can be made within the technical scope of the present disclosure. For example, the wiring pattern 220 extends between the surface 201 and the surface 202 of the circuit substrate 20 in the Z direction. If the circuit substrate 20 includes a plurality of wiring layers, the wiring pattern 220 may also extend in the X direction and the Y direction. The wiring pattern can take a plurality of paths. For example, the configuration shown in each of FIGS. 8B, 9A, and 9B may be combined with the microlenses 50 shown in each of FIGS. 6B and 7B. All or some of the above-described embodiments may be practiced in combination.

An application example of the electronic component 100 according to this embodiment will be described here with reference to FIG. 10. FIG. 10 is a schematic view of equipment EQP including the electronic component 100. As shown in FIG. 10, the electronic component 100 is housed in a package PKG. The equipment EQP can include at least one of an optical device OPT, a control device CTRL, a processing device PRCS, a display device DSPL, a storage device MMRY, and a mechanical device MCHN. The optical device OPT can be implemented by, for example, a lens, a shutter, and a mirror. When the element 110 is a light receiving element, the optical device OPT can form, on the element 110, an image of the light having entered the equipment EQP. When the element 110 is a light emitting element, the optical device OPT can apply the light emitted by the element 110 to an appropriate range. The control device CTRL can control, for example, the circuit substrate 20 arranged in the electronic component 100. The control device CTRL can be, for example, a semiconductor device such as an ASIC.

The processing device PRCS processes a signal output from the electronic component 100. The processing device PRCS can be a semiconductor device such as a CPU or an ASIC for forming an analog front end (AFE) or a digital front end (DFE). The display device DSPL can be an EL display device or a liquid crystal display device that displays information obtained by the electronic component 100. When the element 110 is a light receiving element, the display device DSPL displays an image or the like as the information obtained by the electronic component 100. When the electronic component 100 is used for, for example, a Time-of-Flight (ToF) type distance measurement sensor or the like, the element 110 may be a light receiving element or a light emitting element, and the display device DSPL can display distance information such as a distance image. The storage device MMRY is a magnetic device or a semiconductor device that stores the information obtained by the electronic component 100. The storage device MMRY can be a volatile memory such as an SRAM or a DRAM, or a nonvolatile memory such as a flash memory or a hard disk drive.

The mechanical device MCHN can include a moving or propulsion unit such as a motor or an engine. In the equipment EQP, the signal output from the electronic component 100 is displayed on the display device DSPL or transmitted to an external device by a communication device (not shown) included in the equipment EQP. Hence, the equipment EQP may further include the storage device MMRY and the processing device PRCS in addition to the memory circuits and arithmetic circuits included in the electronic component 100. The mechanical device MCHN may be controlled based on the signal output from the electronic component 100.

In addition, the equipment EQP is suitable for electronic equipment such as an information terminal (for example, a smartphone or a wearable terminal) which has a shooting function or a camera (for example, an interchangeable lens camera, a compact camera, a video camera, or a monitoring camera). The mechanical device MCHN in the camera can drive the components of the optical device OPT in order to perform zooming, an in-focus operation, and a shutter operation. Alternatively, the mechanical device MCHN in the camera can move the electronic component 100 arranged with the element substrate 10 in order to perform an anti-vibration operation. When the element 110 of the electronic component 100 is a light receiving element, the element 110 can function as an image capturing element used for shooting. When the element 110 is a light emitting element, the element 110 can be used to, for example, detect the distance to the object in a focusing operation. When the electronic component 100 is used for the distance measurement sensor, the element 110 may be a light receiving element or a light emitting element, as described above.

Furthermore, the equipment EQP can also be applied to an onboard camera mounted in transportation equipment such as a vehicle, a ship, an airplane, or an industrial robot. The mechanical device MCHN in the transportation equipment can be used as a moving device. The equipment EQP as the transportation equipment is suitable for a device that transports the electronic component 100 or a device that uses a shooting function to assist and/or automate driving (steering). The processing device PRCS for assisting and/or automating driving (steering) can perform, based on the information obtained by the electronic component 100, processing for operating the mechanical device MCHN as a moving device. The equipment EQP incorporating the electronic component 100 can be widely applied to equipment using object recognition such as an intelligent transport system (ITS), in addition to the transportation equipment. Alternatively, the equipment EQP may be medical equipment such as an endoscope, measurement equipment such as a distance measurement sensor, analysis equipment such as an electron microscope, or office equipment such as a copy machine.

According to the present disclosure, it is possible to provide a technique advantageous for further miniaturization of an electronic component.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-067615, filed Apr. 16, 2025, which is hereby incorporated by reference herein in its entirety.

What is claimed is:

1. An electronic component comprising:
an element substrate having a first surface including a central region where a plurality of elements are arranged, and a peripheral region where a first electrode is arranged;
an optical member having a second surface arranged to face the first surface; and
a circuit substrate arranged along at least one side of the element substrate, having a third surface arranged to face the second surface, and including a second electrode arranged on the third surface,
wherein
a third electrode and a fourth electrode electrically connected to each other are arranged on the second surface of the optical member,
the third electrode is arranged at a position overlapping the first electrode in an orthogonal projection to a virtual plane including the first surface, and is electrically connected to the first electrode via a first conductive member which is a bump, and
the fourth electrode is arranged at a position overlapping the second electrode in an orthogonal projection to the virtual plane, and is electrically connected to the second electrode via a second conductive member which is a bump.

2. The component according to claim 1, wherein
in an orthogonal projection to the virtual plane,
an opening portion is provided in the circuit substrate, and
the element substrate is arranged to be surrounded by an inner edge of the opening portion.

3. The component according to claim 1, wherein the third surface is arranged on the virtual plane.

4. The component according to claim 1, wherein a thickness of the element substrate in a direction crossing the first surface is less than a thickness of the circuit substrate in the crossing direction.

5. The component according to claim 1, wherein a thickness of the element substrate in a direction crossing the first surface is not less than a thickness of the circuit substrate in the crossing direction.

6. The component according to claim 1, wherein the third electrode and the fourth electrode are arranged integrally in the second surface.

7. The component according to claim 1, wherein a wiring pattern electrically connecting the third electrode and the fourth electrode includes a first portion arranged on a fourth surface of the optical member on the opposite side of the second surface, a second portion connecting the third electrode and the first portion, and a third portion connecting the fourth electrode and the first portion.

8. The component according to claim 1, wherein
the optical member includes a concave portion in the second surface, and
in an orthogonal projection to the virtual plane, an outer edge of the concave portion is arranged between the central region and an outer edge of the element substrate.

9. The component according to claim 1, wherein
the optical member includes a concave portion in the second surface, and
in an orthogonal projection to the virtual plane, an outer edge of the concave portion is arranged outside an outer edge of the element substrate.

10. The component according to claim 9, wherein the third electrode is arranged in the concave portion.

11. The component according to claim 9, wherein at least a part of the element substrate is arranged in the concave portion.

12. The component according to claim 9, wherein a fifth surface of the element substrate on the opposite side of the first surface is arranged at the same height as an outer edge portion surrounding the concave portion of the second surface with respect to a fourth surface of the optical member on the opposite side of the second surface, or is arranged at a position closer to the fourth surface than the outer edge portion.

13. The component according to claim 9, wherein a surface of the element substrate on an opposite side of the first surface is arranged at a position farther from a fourth surface of the optical member on an opposite side of the second surface than an outer edge portion surrounding the concave portion of the second surface.

14. The component according to claim 1, wherein a plurality of microlenses are arranged on the second surface of the optical member so as to correspond to the plurality of elements, respectively.

15. The component according to claim 14, wherein a height of each of the plurality of microlenses is not more than 1/2 a diameter of each of the plurality of microlenses.

16. The component according to claim 1, wherein a resin is arranged in a gap between the optical member and the circuit substrate.

17. The component according to claim 1, wherein
a plurality of first electrodes including the first electrode, a plurality of third electrodes including the third electrode, and a plurality of first conductive members including the first conductive member and configured to connect each of the plurality of first electrodes to a corresponding third electrode among the plurality of third electrodes are arranged, and
the plurality of first conductive members have a same thickness in a direction crossing the first surface.

18. The component according to claim 1, wherein an electric circuit configured to operate the plurality of elements is arranged in the circuit substrate.

19. The component according to claim 1, wherein each of the plurality of elements includes at least one of a light receiving element and a light emitting element.

20. Equipment comprising:
the electronic component according to claim 1; and
a processing device configured to process a signal output from the element substrate.
